(19) United States
(12) Patent Application Publication
(10) Pub. No.: US 2008/0285243 A1
(43) Pub. Date: Nov. 20, 2008

(54) STORAGE APPARATUS AND FLEXIBLE PRINTED BOARD UNIT

(75) Inventor: Shigeru Kagawa, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/119,289

(22) Filed: May 12, 2008

(30) Foreign Application Priority Data
May 18, 2007 (JP) 2007-132293

(51) Int. Cl. H05K 1/00

(52) U.S. Cl. 361/749

(57) ABSTRACT

A storage apparatus includes an enclosure that has an opening in a bottom, and a carriage block. A flexible printed board has an upper part and a lower part, and a connector attached on an opposed surface of the lower part to a bottom plate of the enclosure inserted through the opening. A connector packing is fixed around the connector, with a catching part that stretches toward the flexible printed board. The flexible printed board has a first opening formed in the lower part, into which the catching part of the connector packing is infixed and a second opening formed in the upper part, into which the catching part of the connector packing fixed into the first opening is further fixed with the upper part folded on the lower part.

This application relates to a storage apparatus such as a hard disk drive. More particularly, this application relates to a storage apparatus having a carriage block and a flexible printed board connected to the carriage block.

### BACKGROUND

A hard disk drive houses a carriage block in its enclosure. Under a bottom plate of the enclosure, a printed board is externally screwed. A flexible printed board connected to the carriage block has a connector. The connector is inserted through an opening formed in the bottom plate of the enclosure and is then connected to the printed board, which is externally screwed onto the bottom plate of the enclosure. A connector packing made of a material such as gum is provided so as to surround the connector, thereby sealing the enclosure.

For a small size hard disk drive, the flexible printed board is commonly mounted with its body folded to make a mounting area of the flexible printed board larger. Thus, the flexible printed board has an upper part having a connection of a cable whose end connects to the carriage and a lower part folded under the upper part. The lower part has the connector.

Prior to attaching the flexible printed board to the enclosure, the flexible printed board is engaged with its body folded. The upper part and the lower part are engaged with metal catching parts with the upper part folded on the lower part. Then the engaged flexible printed board is attached to the enclosure by using screws, etc.

However, when engaging the upper part and the lower part with the metal catching parts, the following problem arises: when carrying the flexible printed board with its body engaged, dust is caused due to friction with the metal catching parts. Since the hard disk drive is assembled in a clean room, causing dust in the clean room is unfavorable in manufacturing.

In the manufacturing process of the hard disk drive, it is convenient to fix the connector packing on the enclosure or the flexible printed board. In a conventional way, the connector packing is affixed with a double-stick tape or the like on the enclosure and then the flexible printed board is attached thereon. The disadvantage of using the double-stick tape is that it increases the number of parts. In addition, the double-stick tape used in the hard disk drive has a non-gas-producing property when an ambient temperature changes. Those factors make a cost reduction of the hard disk drive difficult.

### SUMMARY

In accordance with an aspect of an embodiment, a storage apparatus includes an enclosure that has an opening in a bottom plate thereof, and a carriage block rotatably supported by the enclosure. A flexible printed board has an upper part on which a cable connected to the carriage block is attached and a lower part opposed to an inside surface of the upper part, attached to the enclosure. A connector is attached on an opposed surface of the lower part to a bottom plate of the enclosure inserted through the opening, and a connector packing is fixed around the connector. A catching part stretches toward the flexible printed board. The flexible printed board has a first opening formed in the lower part, into which the catching part of the connector packing is fixed and a second opening formed in the upper part, into which the catching part of the connector packing is fixed into the first opening is further is fixed with the upper part folded on the lower part.

### BRIEF DESCRIPTION OF THE DRAWINGS

FIG. 1A is an outline drawing of a hard disk drive viewed from the top face.

FIG. 1B is an outline drawing of the hard disk drive viewed from the underside.

FIG. 2 is a development view of a flexible printed board according to the present invention.

FIG. 3 shows an exploded perspective view of the flexible printed board and the connector packing.

FIG. 4A is a top view of the flexible printed board with its body folded and engaged with the connector packing.

FIG. 4B is a side view of the flexible printed board with its body folded and engaged with the connector packing.

FIG. 4C is a bottom view of the flexible printed board with its body folded and engaged with the connector packing.

### DESCRIPTION OF THE PREFERRED EMBODIMENT

Referring to the accompanying drawings, an embodiment of the application will be discussed.

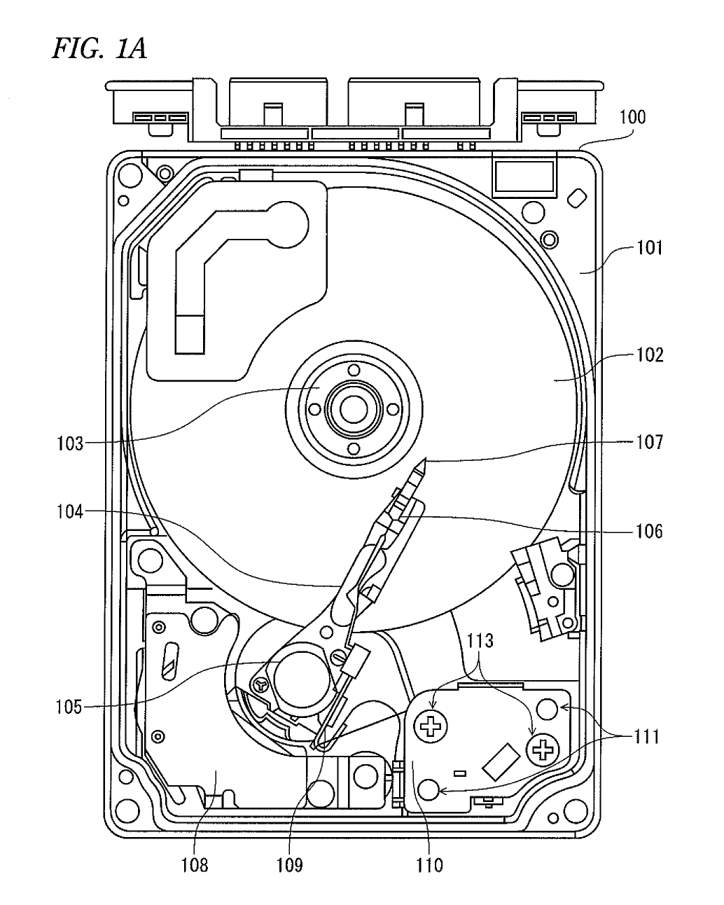

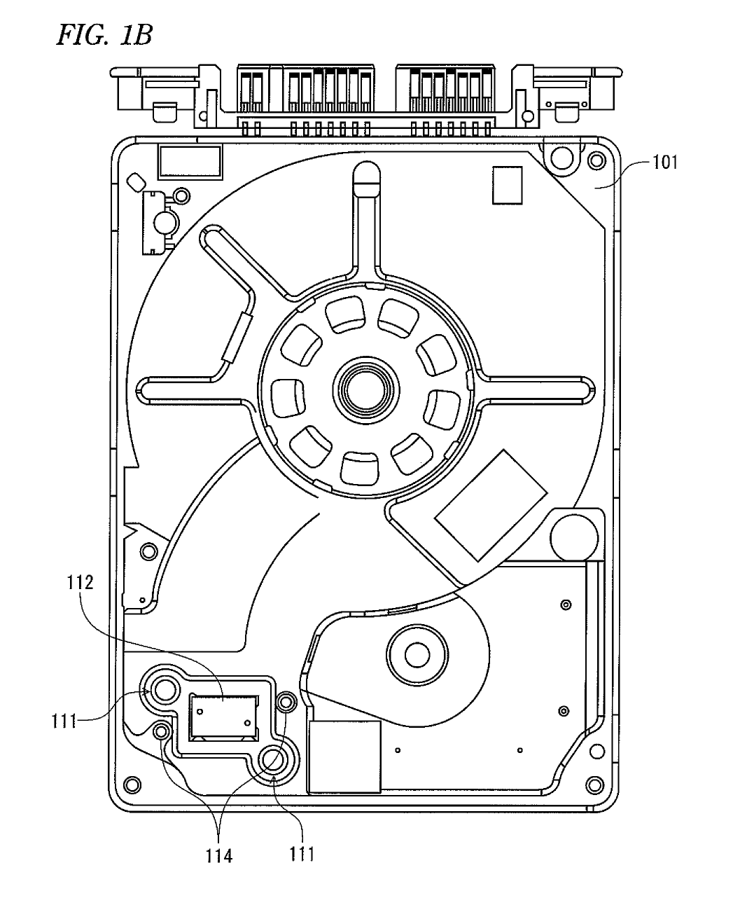

FIG. 1A and FIG. 1B are outline drawings of an example of a storage apparatus, i.e., outline drawings of a hard disk drive 100. FIG. 1A is an outline drawing of the hard disk drive viewed from the top face. FIG. 1B is an outline drawing of the hard disk drive viewed from the underside.

The hard disk drive 100 has a box-shaped enclosure 101. The enclosure 101 encloses an internal space, in other words, an enclosed space of the hard disk drive 100. The enclosure 101 has a lid (not illustrated), i.e., a cover. Thus, the enclosed space enclosed with the cover and the enclosure 101 is sealed. The enclosure 101 or the cover is molded from a single plate by press working.

In the enclosed space, one or more magnetic disks 102 are housed as storage media. The magnetic disks 102 are mounted on a revolving shaft of a spindle motor 103. The spindle motor 103 is able to rotate the magnetic disks 102 at a high speed, e.g., 4200 rpm, 5400 rpm or 7200 rpm. The magnetic disks 102 are, for example, 1.8 inch in diameter.

In the enclosed space, a carriage 104 is also housed. The carriage 104 has a carriage block 105. The carriage block 105 is rotatably attached to a spindle vertically stretching from a bottom plate of the enclosure 101 in a perpendicular direction. A carriage block 105 is formed from an aluminum plate by the extrusion molding method, etc.

At the ends of a plurality of carriage arms supported by the carriage block 105 in a lateral direction, a head suspension 106 is attached to each arm respectively. Further, at the ends of the head suspensions 106, a flying head sliders 107 are attached respectively. The flying head sliders 107 each have a head element, i.e., an electromagnetic conversion element.

Since aerial current flows over the surface of the magnetic disk 102 due to the rotation of the magnetic disk 102, a positive pressure, in other words, a buoyant force and a negative pressure caused by the aerial current are applied to the flying head slider 107. By keeping the buoyant force, the negative pressure and a thrust force of the head suspension 106 in equilibrium, the head slider 107 can fly with a relatively high rigidity while the magnetic disks 102 rotate.

When the carriage 104 rotates about the spindle and the flying head slider 107 flies, the flying head slider 107 can move over a surface of the magnetic disk 102. Therefore, the flying head slider 107 having the electromagnetic conversion element traverses data zones between an outermost recording track and an innermost track. Thus, the electromagnetic conversion element attached on the flying head slider 107 is positioned over a targeted recording track.

The carriage block 105 connects with a source of power such as a voice coil motor (VCM) 108. The carriage block 105 rotates about the spindle by the VCM 108. With the rotation of the carriage block 105, the head suspension 106 attached to the carriage arm moves.

The carriage block 105 further comprises a flexible printed board unit 109. The flexible printed board unit 109 has a movable part at the end of a cable attached to the flexible printed board 110 that is attached to the enclosure. In a pair of openings 111 formed in the flexible printed board 110, the catching parts of a connector packing (not illustrated) are infixed. The flexible printed board 110 is engaged with its upper part folded on the lower part.

After engagement, the flexible printed board 110 is attached to the enclosure with its connector infixed to an opening 112 formed in the bottom plate of the enclosure. Then the flexible printed board 110 is screwed to the enclosure 101 with the screws 113, etc.

Further, on the underside of the enclosure, a pair of screw holes 114 are formed. By screwing screws in the screw holes 114, a printed board (not illustrated) is attached externally on the underside of the enclosure. On the printed board, some parts including the connector are connected.

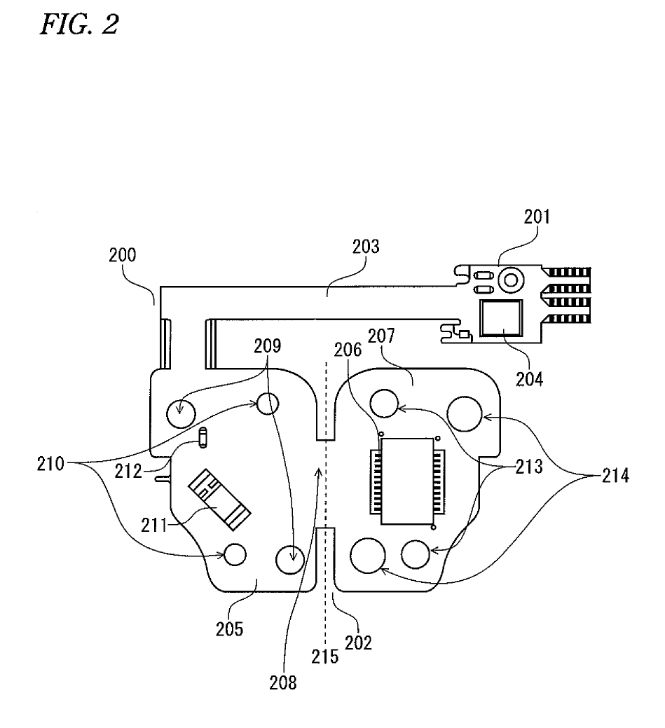

FIG. 2 is a view of the flexible printed board 200 before installation. The flexible printed board 200 includes a movable part 201, a fixed part 202 and a cable 203. The flexible printed board 200 is constructed of an insulation thin sheet, a conductive layer deposited on the thin sheet and a protective layer deposited on the conductive layer. In the conductive layer, a wiring pattern is formed by using a conductive material such as copper. The thin sheet and the protective layer are made of a resin material such as polyimide. Between the thin sheet and the conductive layer or the conductive layer and the protective layer, an adhesion layer is inserted.

On the movable part 201, ahead IC (Integrated circuit) 204 is mounted previously. The head IC 204 connects to a read/write head, in other words, the electromagnetic conversion element through the flexible printed board unit 109.

The fixed part 202 comprises an upper part 205 to which the cable 203 stretching from the movable part 201 connects, a lower part 207 having a connector 206 connected to the printed board externally attached on the enclosure and a joint 208 by which the upper part 205 and the lower part 207 are joined. The upper part 205 has a first pair of openings 209 into which screws to screw the flexible printed board to the enclosure are screwed and a second pair of openings 210 used for engaging the flexible printed board 110.

On the upper part 205, a shock sensor 211 and a thermistor 212 are mounted. The shock sensor 211 senses a shock to the hard disk drive 100. The thermistor 212 senses a temperature in the enclosure 101.

The lower part has a third pair of openings 213 into which the screws screwed into the first pair of openings 209 are further screwed and a fourth pair of openings 214 used for engaging the flexible printed board 110.

The first pair of openings 209 and the third pair of openings 213 are formed symmetrically on either side of a symmetric axis 215 that lies between the upper part 205 and the lower part 207. Likewise, the second pair of openings 210 and the fourth pair of openings 214 are formed symmetrically on either side of the symmetric axis 215 that lies between the upper part 205 and the lower part 207. The second pair of openings 210 can be smaller than the fourth pair of openings 214 in diameter to facilitate insertion of the catching parts to the upper part 205 and the lower part 207 that are laid over each other when installed.

Support plates not illustrated in FIG. 2 are affixed onto both surfaces of the upper part 205 and the lower part 207 that are opposed each other when the flexible printed board 200 is folded into two. The support plates are formed from sheet metals, etc.

Prior to attaching the flexible printed board 200 to the enclosure, the flexible printed board comprising the upper part 205 and the lower part 207 is folded in half along the symmetric axis 215.

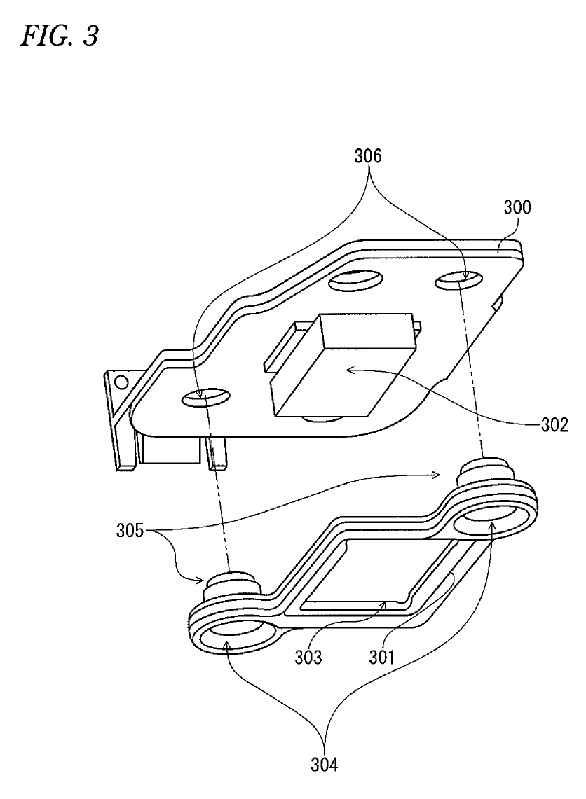

Referring to FIG. 3, a method to engage the flexible printed board 200 folded in half will be discussed.

In FIG. 3, a folded flexible printed board 300 and a connector packing 301 fixed from an opposed surface of the lower part to the enclosure are shown.

A connector 302 attached onto the opposed surface of the lower part to the enclosure is inserted into a rectangle opening formed in the bottom plate of the enclosure 101. The connector 302 protruded from the bottom plate of the enclosure 101 to the outside is further inserted into the printed board aforementioned.

There is a gap between the connector 302 and the opening formed in the bottom plate of the enclosure. Therefore, the enclosure of the hard disk drive cannot be sealed up sufficiently. To infill the gap between the connector 302 and the opening, the connector packing 301 is used. By using the connector packing 301, the enclosure 101 is kept sealed.

The connector packing 301 includes a rectangle part 303 with which the gap between the connector 302 and the opening formed in the bottom plate of the enclosure 101 is infilled and a pair of loop parts 304 infilling the gaps around the screw holes into which the screws screwing the printed board on which the connector 302 connects onto the enclosure 101 is screwed. The connector packing 301 is made of a fairly flexible generally non-abrasive material such as gum or resin by molding.

For a small size hard disk drive using a 1.8-inch storage medium, a layout of parts in the enclosure is optimized in order to use the space efficiently for downsizing. Hence, each part is arranged so as to seal a plurality of openings formed in the enclosure with one packing.

The connector packing 301 has catching parts 305 of sufficient extent to catch the flexible printed board 300. The catching parts 305 are inserted into the openings 306 comprising the second opening 210 and the fourth opening 214.

It is favorable that a length of the catching parts 305 be greater than a summation of thicknesses of the upper part 205 and the lower part 207 of the flexible printed board 300. It is also favorable that the catching parts 305 be larger than the openings 306 formed in the flexible printed board in diameter. This is because a frictional force that engages the upper part 205 and the lower part 207 is generated when the catching parts 305 that are larger than the openings 306 in diameter are fixed into the openings 306.

Furthermore, forming the catching parts 305 in cylindrical shape allows fabricating the connector packing in the same manner as with the conventional one. Moreover, by forming the end of the catching parts 305 in taper shape, insertion of the catching parts 305 into the openings 306 formed in the flexible printed board 300 is facilitated. Where making the catching parts 305 in taper shape, it is important that the lengths of the catching parts except the taper parts are greater than the summation of the thicknesses of the upper part 205 and the lower part 207, thereby engaging the flexible printed board 300 with its body folded.

In this embodiment, the catching parts 305 are integral with the loop parts 304. However, the catching parts can be laid out arbitrarily according to the wiring pattern or a parts layout of the flexible printed board 300. Here, the catching parts 305 are in cylindrical shape, however, they can be rectangular and so on.

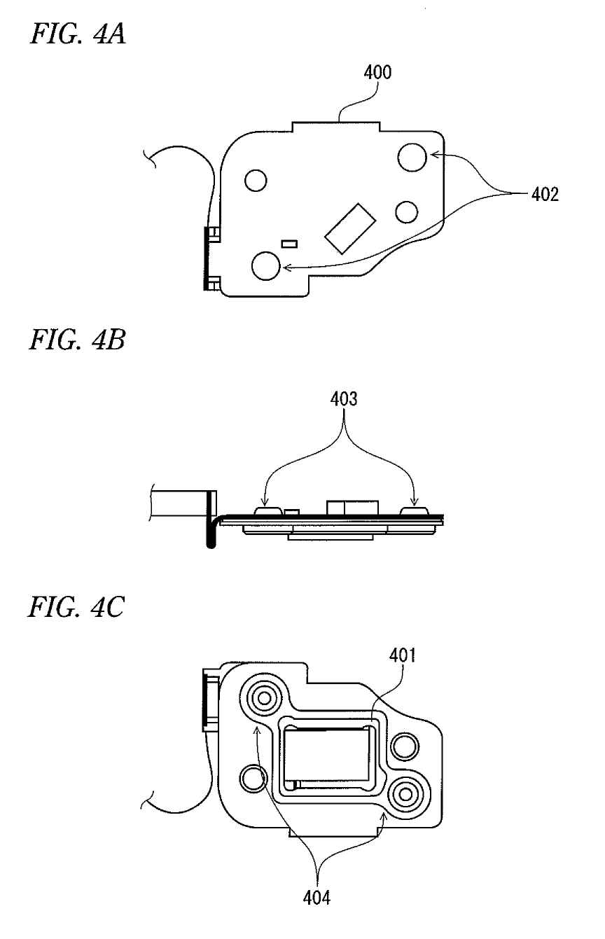

FIG. 4A-4C show the three views of a flexible printed board 400 fixed with a connector packing 401.

The catching parts 403 of the connector packing 401 are fixed into the openings 402 where the second pair of openings 214 overlies the fourth pair of openings 214 from under the lower part 207. Thus, the upper part 205 and the lower part 207 are engaged with the catching parts 403 with the upper part 205 folded on the lower part 207.

As shown in FIG. 4B, the length of the catching parts 403 of the connector packing is greater than the summation of the thicknesses of the upper part 205 and the lower part 207. Therefore, the catching parts 403 pass through the second pair of openings 210 formed in the upper part 205 to the upper surface of the flexible printed board 400. Thus, the upper part 205 and the lower part 207 are engaged securely with the catching parts 403 with the upper part 205 folded on the lower part 207. Thus, no metal parts for engaging the upper part 205 and the lower part 207 are needed and therefore dust is not created as with the metal catching parts. This helps to reduce the dust caused in the clean room in the manufacturing the hard disk drive.

As seen in FIG. 4C, the connector packing 401 is fixed onto the flexible printed board 400 with its catching parts 403 formed on the loop parts 404. Thus, the connector packing 401 can be fixed onto the flexible printed board 400 without using the double-stick tape or the like, thereby preventing a displacement of the connector packing while attaching the flexible printed board 400 to the enclosure 101. Thus, the flexible printed board can be attached to the enclosure more easily. Accordingly, the production cost of the hard disk drive can be curbed with the present invention.

What is claimed is:

1. A storage apparatus comprising:
an enclosure having an opening in a bottom plate thereof;
a carriage block rotatably supported by said enclosure;
a flexible printed board having an upper part on which a cable connected to said carriage block is attached and a lower part opposed to an inside surface of said upper part, attached to said enclosure;
a connector attached on an opposed surface of said lower part to a bottom plate of said enclosure, inserted to said opening; and
a connector packing fixed around said connector, having a flexible non-abrasive catching part that stretches toward said flexible printed board,
wherein said flexible printed board has a first opening formed in said lower part, into which the catching part of said connector packing is fixed and a second opening formed in said upper part, into which the catching part of said connector packing fixed into said first opening is further fixed with said upper part folded on said lower part.

2. The storage apparatus according to claim 1, wherein
said catching part is larger than said second opening in diameter.

3. The storage apparatus according to claim 2, wherein
said upper part further comprises a third opening into which a screw screwing said flexible printed board onto said enclosure; and
said lower part further comprises a fourth opening into which said screw screwed into said third opening is further screwed.

4. The storage apparatus according to claim 3, wherein:
a length of said catching part is greater than a summation of thicknesses of said upper part and said lower part.

5. The storage apparatus according to claim 4, wherein
said catching part is made of a gum material.

6. The storage apparatus according to claim 5, wherein
said flexible printed board is attached to said enclosure with said upper part folded on said lower part.

7. A flexible printed board comprising an upper part having a cable and a lower part folded under said upper part, further comprising:
a connector mounted on said lower part and inserted into an opening formed in a bottom plate of an enclosure on which said flexible printed board is attached;
a first opening formed in said lower part, into which a catching part of a connector packing that is laid out so as to surround said connector is fixed; and
a second opening formed in said upper part, into which the catching part of said connector packing fixed into said first opening is fixed with said upper part folded on said lower part.

8. The flexible printed board according to claim 7, wherein
a catching part that is greater than said second opening in diameter is fixed into said first opening and said second opening.

9. The flexible printed board according to claim 8, wherein
said upper part further comprises a third opening into which a screw screwing said flexible printed board onto said enclosure is screwed; and
said lower part further comprises a fourth opening into which said screw screwed into said third opening is further screwed.
